(19) United States
(12) Patent Application Publication
(10) Pub. No.: US 2026/0059949 A1
(43) Pub. Date: Feb. 26, 2026

(54) DISPLAY PANEL, DISPLAY APPARATUS, AND METHOD FOR MANUFACTURING DISPLAY PANEL

(71) Applicants: KunShan Go-Visionox Opto-Electronics Co., Ltd., Kunshan (CN); Hefei Visionox Technology Co., Ltd., Hefei (CN)

(72) Inventors: Zhen FU, Hefei (CN); Xu QIAN, Hefei (CN); Ying SHEN, Kunshan (CN); Shuangbing ZHANG, Hefei (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/313,753

(22) Filed: Aug. 28, 2025

(30) Foreign Application Priority Data
Jun. 28, 2024 (CN) 202410865317.5

(51) Int. Cl. H10K 59/122; H10K 59/40; H10K 59/80

(52) U.S. Cl. CPC H10K 59/122; H10K 59/873; H10K 59/40

(57) ABSTRACT

Embodiments of the present application provide a display panel, a method for manufacturing the display panel, and an electronic device, relating to the field of display technology. In the display panel, the second isolation portion extends relative to the first isolation portion to form an undercut structure, which can interrupt a full-surface evaporated film layer at this location. An orthographic projection of the conductive portion on the substrate at least partially overlaps with an orthographic projection of the second isolation portion on the substrate, and an orthographic projection of the first isolation portion on the substrate is located within a range of the orthographic projection of the conductive portion on the substrate. This configuration allows a surface of the isolation structure facing the isolation opening to form a flow guide surface with good flow smoothness, enhancing the flow smoothness of this surface. When forming the inorganic encapsulation layer, film-forming material can flow smoothly along this surface, facilitating continuous film formation on the surface and resulting in an inorganic encapsulation layer with relatively uniform film thickness. This improves the stress resistance and encapsulation effectiveness of the inorganic encapsulation layer.

### CROSS-REFERENCE TO RELATED APPLICATIONS

The present application claims priority to the Chinese Patent Application 202410865317.5, filed on Jun. 28, 2024, and the entire contents of the aforementioned application are hereby incorporated by reference in its entirety.

### TECHNICAL FIELD

The present application relates to the technical field of display, and in particular to a display panel, and an electronic device.

### BACKGROUND

The organic light emitting diode (OLED) is regarded as the next-generation flat panel display technology after the liquid crystal display technology, which is widely applied in various consumer electronic products such as mobile phones, televisions, laptop computers and desktop computers due to its excellent color and image quality, and has become the mainstream in display panels.

However, the process performance of current OLED display products still needs to be further improved.

### SUMMARY

In order to overcome the technical problem mentioned in the above background, the present application provides a display panel, a method for preparing a display panel, and an electronic device.

In a first aspect of the present application, a display panel is provided. The display panel includes:
a substrate; and
an isolation structure located on one side of the substrate, and he isolation structure encircling at least one of isolation openings;
wherein the isolation structure includes a conductive portion and an isolation portion;
the isolation portion includes a first isolation portion and a second isolation portion, the conductive portion, the first isolation portion and the second isolation portion being stacked in a direction away from the substrate, and the second isolation portion extending relative to the first isolation portion toward a corresponding one of the isolation openings; and
an orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate.

In a second aspect of the present application, a method for preparing a display panel is further provided. The method includes:
providing a substrate; and
preparing isolation structures on the substrate such that the isolation structures define isolation openings on the substrate, where each of the isolation structures includes a conductive portion and an isolation portion, and the isolation portion includes a first isolation portion and a second isolation portion, the conductive portion, the first isolation portion and the second isolation portion being stacked in a direction away from the substrate, and the second isolation portion extending relative to the first isolation portion toward a corresponding one of the isolation openings; and an orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate.

Embodiments of the present application provide a display panel, a method for preparing a display panel, and an electronic device. In the display panel, an isolation structure is located on a substrate and encircling at least one of isolation openings, and the isolation structure includes a conductive portion and an isolation portion, where the isolation portion includes a first isolation portion and a second isolation portion that are sequentially stacked on the conductive portion in a direction away from the substrate, the second isolation portion extending relative to the first isolation portion toward a corresponding one of the isolation openings. In the above-described design, the first isolation portion and the second isolation portion form an undercut structure at which an entire surface of an evaporated film layer is disconnected. In addition, an orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate, which allows a surface on a side of the isolation structure facing the isolation opening to form a guide surface with good flow smoothness, and may increase the flow smoothness of a film-forming material on the surface of the isolation structure in the process of preparing an inorganic encapsulation layer, so that the film-forming material continuously forms a film on the surface of the isolation structure, forming an inorganic encapsulation layer with a relatively uniform film thickness, thereby improving the stress resistance and encapsulation effect of the film layer of the inorganic encapsulation layer.

### BRIEF DESCRIPTION OF THE DRAWINGS

In order to illustrate the technical solutions of embodiments of the present application more clearly, the drawings required in the embodiments will be briefly introduced below. It should be understood that the following drawings only show some embodiments of the present application, and therefore should not be construed as a limitation on the scope. For those of ordinary skill in the art, other related drawings can be obtained from these drawings without involving any inventive effort.

FIG. 1 illustrates a first schematic diagram of part of a film layer structure in a display panel according to an embodiment of the present application;

FIG. 2 illustrates a positional relationship diagram of isolation structures and isolation openings in the display panel according to an embodiment of the present application;

FIG. 3 illustrates a first structural schematic diagram of an isolation structure according to an embodiment of the present application;

FIG. 4 illustrates a second structural schematic diagram of an isolation structure according to an embodiment of the present application;

FIG. 5 illustrates a third structural schematic diagram of an isolation structure according to an embodiment of the present application;

FIG. 6 illustrates a second schematic diagram of part of a film layer structure in a display panel according to an embodiment of the present application;

FIG. 7 illustrates a third schematic diagram of part of a film layer structure in a display panel according to an embodiment of the present application;

FIG. 8 illustrates a fourth schematic diagram of part of a film layer structure in a display panel according to an embodiment of the present application;

FIG. 9 illustrates a first cross-sectional schematic diagram of the display panel along line AA in FIG. 2;

FIG. 10 illustrates a second cross-sectional schematic diagram of the display panel along line AA in FIG. 2;

FIG. 11 illustrates a schematic diagram showing the distribution of regions of the display panel;

FIG. 12 illustrates a first cross-sectional schematic diagram of a first active area in FIG. 11;

FIG. 13 illustrates a second cross-sectional schematic diagram of a first active area in FIG. 11;

FIG. 14 illustrates a third cross-sectional schematic diagram of the display panel along line AA in FIG. 2;

FIG. 15 illustrates a schematic diagram of a possible film layer structure of a light-emitting device;

FIG. 16 illustrates a fourth cross-sectional schematic diagram of the display panel along line AA in FIG. 2;

FIG. 17 illustrates a schematic diagram showing the relationship between a film thickness and stress;

FIG. 18 illustrates a fifth cross-sectional schematic diagram of the display panel along line AA in FIG. 2;

FIG. 19 illustrates a sixth cross-sectional schematic diagram of the display panel along line AA in FIG. 2;

FIG. 20 illustrates a schematic flowchart of a method for preparing a display panel according to an embodiment of the present application;

FIG. 21 illustrates a schematic flowchart of a possible implementation of step S12 in FIG. 20;

FIG. 22 illustrates a process diagram corresponding to FIG. 21;

FIG. 23 illustrates a schematic flowchart of a further possible implementation of step S12 in FIG. 20;

FIG. 24 illustrates a process diagram corresponding to FIG. 23; and

FIG. 25 illustrates a process diagram of preparing isolation portions according to an embodiment of the present application.

List of reference signs: 1—Display panel; 11—Substrate; 12—Isolation structure; 1201—Isolation opening; 121—Conductive portion; 122—Isolation portion; 1221—First isolation portion; 1222—Second isolation portion; 1222a—First isolation sub-portion; 1222b—Second isolation sub-portion; 12221—Groove; 13—Pixel defining layer; 1301—Pixel opening; 14—Light-emitting device; 141—First electrode; 142—Light-emitting material layer; 143—Second electrode; 151—First encapsulation layer; 1511—Encapsulation unit; 152—Second encapsulation layer; 153—Third encapsulation layer; 16—Touch functional layer; 161—First touch trace; 162—Second touch trace; 17—Filter unit; 20—Conductive material layer; 30—Isolation material layer; 40—Sacrificial material layer; 50—Photoresist layer; 501—Adhesive layer opening.

### DETAILED DESCRIPTION OF THE EMBODIMENTS

In order to make the objectives, technical solutions and advantages of embodiments of the present application clearer, the technical solutions in the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application. Based on the embodiments of the present application, all other embodiments obtained by those of ordinary skill in the art without involving any inventive effort shall fall within the scope of protection of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center”, “upper”, “lower”, “vertical”, “horizontal”, “inner” and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

Increasing the density (i.e. pixel density) of light-emitting devices in a display panel is an important way to improve the display effect. However, display panels currently made by using the fine metal mask (FMM) technology are unable to further increase the density of light-emitting devices due to technical limitations. The inventors have found, after long-term research, that in order to solve the technical problem that the density of light-emitting devices cannot be further increased, isolation structures are provided in some display panels, and during the full-layer evaporation of light-emitting material layers and cathodes, the light-emitting material layers and the cathodes can be disconnected at the positions of the isolation structures, and light-emitting devices of different colors can be formed in different isolation openings by means of multiple evaporation and multiple etching processes, i.e., patterning of the light-emitting devices.

Reference is made to relevant technical solutions of an isolation structure and an encapsulation layer disclosed in patents PCT/CN2023/134518, 202310759370.2, 202310740412.8, 202310707209.0, 202311499823.9, 202310692671.8, 202311091555.7, and 202311346196.5, the contents of which are incorporated herein by reference.

In the above-mentioned display panel, the inventors have found that after the display panel is deformed due to the action of an external force, the display effect of the display panel will be affected. Through research, the inventors have found that the main reasoning for the above technical problems is the rupture of an inorganic encapsulation layer for encapsulating the light-emitting devices, which makes the inorganic encapsulation layer fail to encapsulate the light-emitting devices, allowing moisture to invade the light-emitting devices, thereby affecting the display effect of the display panel. After conducting a technical analysis of a rupture position of the inorganic encapsulation layer, the inventors have found that the rupture position of the inorganic encapsulation layer is mainly located in an area where a film thickness of the inorganic encapsulation layer is relatively small in the isolation structure.

In order to solve the above-mentioned technical problem, the inventors have innovatively designed the following technical solutions. The specific implementations of the present application will be described in detail below with reference to the accompanying drawings. It should be noted that the defects of the above solutions in the prior art are the results obtained by the inventors after practice and careful research.

Therefore, the process of discovering the above technical problem and the solutions proposed in the following embodiments for the above problem should be regarded as the contributions made by the inventors to the present application during invention and creation, and should not be construed as the technical content that is well known to those skilled in the art.

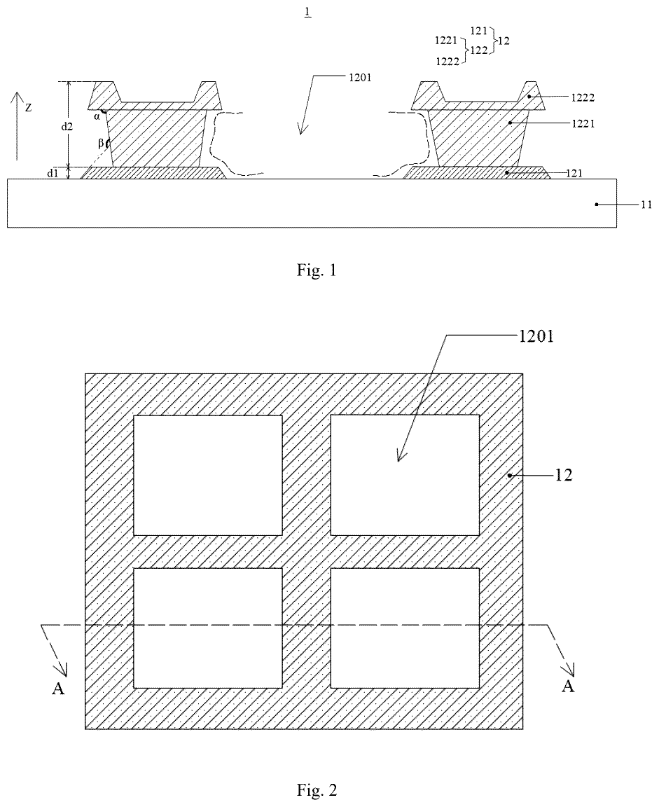

Referring to FIGS. 1 and 2, FIG. 1 illustrates a structural schematic diagram of a display panel according to an embodiment of the present application, and FIG. 2 illustrates a schematic diagram showing the distribution of isolation structures and isolation openings in FIG. 1. In this embodiment, the display panel 1 includes a substrate 11 and an isolation structure 12. The isolation structure 12 are located on the substrate 11, and the isolation structure 12 encircling at least one of isolation openings 1201.

The substrate 11 is of a multi-layer structure, and the substrate 11 includes at least a plurality of metal layers and an insulating layer located between adjacent metal layers. A pixel drive circuit for providing driving signals to the light-emitting devices is formed in the substrate 11.

The isolation structure 12 includes a conductive portion 121 and an isolation portion 122, where the isolation portion 122 includes a first isolation portion 1221 and a second isolation portion 1222, and the conductive portion 121, the first isolation portion 1221 and the second isolation portion 1222 are stacked in a direction away from the substrate 11. The second isolation portion 1222 extends relative to the first isolation portion 1221 in a direction toward a corresponding one of the isolation openings 1201.

In this embodiment, an orthographic projection of the conductive portion 121 on the substrate 11 at least partially coincides with an orthographic projection of the second isolation portion 1222 on the substrate 11, and an orthographic projection of the first isolation portion 1221 on the substrate 11 is located within the orthographic projection of the conductive portion 121 on the substrate 11.

In the above structure, for the same corresponding isolation opening 1201, the second isolation portion 1222 extends relative to the first isolation portion 1221 to form an undercut structure at which an entire surface of an evaporated film layer may be disconnected. In addition, the orthographic projection of the conductive portion 121 on the substrate 11 at least partially coincides with the orthographic projection of the second isolation portion 1222 on the substrate 11, and the orthographic projection of the first isolation portion 1221 on the substrate 11 is located within the orthographic projection of the conductive portion 121 on the substrate 11, which allows a surface on a side of the isolation structure facing the isolation opening 1201 to form a guide surface with good flow smoothness (shown by dashed lines in the figure). In the process of preparing an inorganic encapsulation layer, a film-forming material may move smoothly along the surface, so that the film-forming material continuously forms a film on the surface, forming an inorganic encapsulation layer with a relatively uniform film thickness, thereby improving the stress resistance and encapsulation effect of the film layer of the inorganic encapsulation layer.

In this embodiment, referring again to FIG. 1, a first included angle α between a side of the second isolation portion 1222 facing the substrate 11 and a side of the first isolation portion 1221 facing the substrate 11 is an obtuse angle. The first included angle α is set to an obtuse angle to increase the smoothness of the surface on the side of the isolation structure facing the isolation opening 1201, thereby improving the flow smoothness.

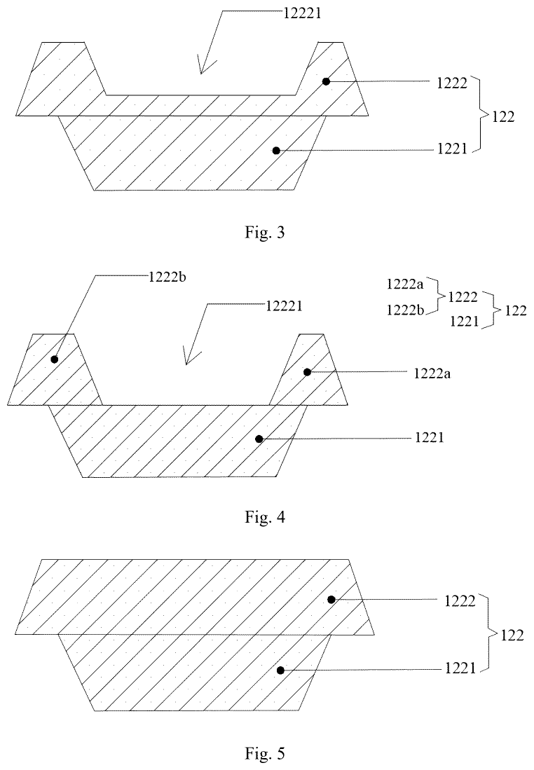

Referring to FIGS. 3 and 4, in a possible implementation of this embodiment, a groove 12221 recessed toward the substrate 11 is provided on a side of the second isolation portion 1222 away from the substrate 11, where a bottom surface of the groove 12221 may be part of the second isolation portion 1222, as shown in FIG. 3; and the bottom surface of the groove 12221 may also be a surface of the first isolation portion 1221 away from the substrate 11, as shown in FIG. 4. Referring to FIG. 4, the second isolation portion 1222 surrounding the periphery of each isolation opening includes a first isolation sub-portion 1222a and a second isolation sub-portion 1222b separated from each other, and orthographic projections of the first isolation sub-portion 1222a and the second isolation sub-portion 1222b on the substrate 11 extend relative to opposite sides of the orthographic projection of the first isolation portion 1221 on the substrate 11, respectively. On a first cross-section perpendicular to a plane where the substrate 11 is located and in a direction of a line connecting centers of two adjacent isolation openings 1201, cross-sectional shapes of the first isolation sub-portion 1222a and the second isolation sub-portion 1222b include a trapezoid.

In this implementation, materials of the first isolation portion 1221 and the second isolation portion 1222 each include an inorganic material (e.g., silicon oxide, silicon nitride), and in this case, the first isolation portion 1221 and the second isolation portion 1222 may be made using the same process. In addition, it is also possible that the material of the first isolation portion 1221 is an organic material, and the material of the second isolation portion 1222 is an inorganic material. In this implementation, the first isolation portion 1221 may also be a conductive isolation portion, and the material of the first isolation portion 1221 includes a conductive metal material.

Referring to FIG. 5, in a further possible implementation of this embodiment, a flat surface is provided on the side of the second isolation portion 1222 away from the substrate 11, in which implementation, the materials of the first isolation portion 1221 and the second isolation portion 1222 each include an organic material, and in which case the first isolation portion 1221 and the second isolation portion 1222 are made using the same process. In addition, it is also possible that the material of the first isolation portion 1221 is an inorganic material, and the material of the second isolation portion 1222 is an organic material. In this implementation, the first isolation portion 1221 may also be a conductive isolation portion, and the material of the first isolation portion 1221 includes a conductive metal material.

Further, referring again to FIG. 1, in this embodiment, an orthographic projection, on the substrate 11, of a bottom surface on the side of the first isolation portion 1221 facing the substrate 11 is located within an orthographic projection, on the substrate 11, of a top surface on a side of the conductive portion 121 away from the substrate 11, that is, the conductive portion 121 extends toward the isolation opening 1201 relative to the bottom surface of the first isolation portion 1221.

Optionally, on a first cross-section perpendicular to a plane where the substrate 11 is located and in a direction of a line connecting centers of two adjacent isolation openings 1201, a shape of the first isolation portion 1221 is an inverted trapezoid.

In this embodiment, the orthographic projection of the second isolation portion 1222 on the substrate 11 is located within the orthographic projection of the conductive portion 121 on the substrate 11; alternatively, the orthographic projection of the second isolation portion 1222 on the substrate 11 fully coincides with the orthographic projection of the conductive portion 121 on the substrate 11; alternatively, the orthographic projection of the conductive portion 121 on the substrate 11 is located within the orthographic projection of the second isolation portion 1222 on the substrate 11.

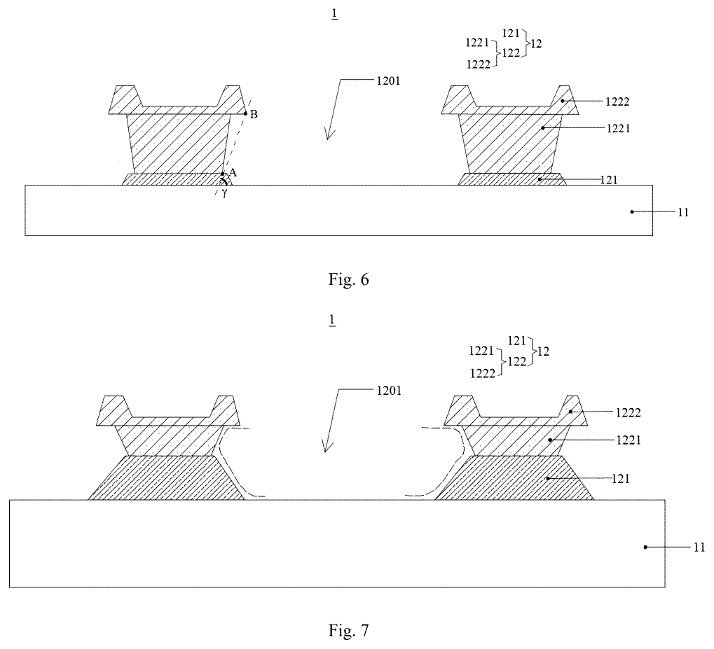

In a possible implementation, referring to FIG. 6, the orthographic projection of the conductive portion 121 on the substrate 11 is located within the orthographic projection of the second isolation portion 1222 on the substrate 11, the first isolation portion 1221 has a first end A which is a side of the first isolation portion 1221 in contact with the conductive portion 121 and is close to the isolation opening 1201, the second isolation portion 1222 has a second end B on a side of the second isolation portion close to the isolation opening 1201, and a connecting surface of the first end A and the second end B forms a preset included angle γ with the plane where the substrate 11 is located, the preset included angle γ being greater than 20°. Illustratively, the preset included angle γ is an acute angle greater than 20°, with the preset included angle γ including 20°, 22°, 25°, 30°, 35°, 42°, 45°, 50°, 56°, 65°, 72°, 80°, 85°, etc. It is designed to ensure that an evaporation electrode is disconnected at the second isolation portion 1222 and that the evaporation electrode has a large overlap height on a side wall of the isolation portion 122 facing the isolation opening 1201.

Further, referring again to FIG. 1, a second included angle β between a side wall of the first isolation portion 1221 facing the isolation opening 1201 and a side wall of the conductive portion 121 facing the isolation opening 1201 is an obtuse angle, which is designed to allow for a smoother transition at a junction of the first isolation portion 1221 and the conductive portion 121, to improve the flow smoothness at the junction. Preferably, the second included angle β is larger than the first included angle α, so that the film-forming material is less resistant when passing through the junction of the first isolation portion 1221 and the conductive portion 121, and more easily reaches an area where the first included angle α is located. This increases the flow smoothness of the entire surface of the isolation structure, so that the film-forming material is continuously formed into a film on the surface of the isolation structure.

In this embodiment, referring again to FIG. 1, a thickness d2 of the isolation portion 122 is 1 to 10 times a thickness d1 of the conductive portion 121. For example, the thickness d2 of the isolation portion 122 is 1, 1.05, 1.23, 1.55, 2.15, 3.05, 4.33, 5.25, 6.15, 7.25, 8.23, 8.79, 9.12, 9.55, 9.87, or 10 times the thickness d1 of the conductive portion 121. Optionally, referring to FIG. 7, when the thickness of the isolation portion 122 is comparable to the thickness of the conductive portion 121, the flow smoothness of a guide surface formed by the surface on the side of the isolation structure 12 facing the isolation opening 1201 is better, the guide surface is closer to a C-shape, and it is advantageous to form an inorganic encapsulation layer with a relatively uniform film thickness.

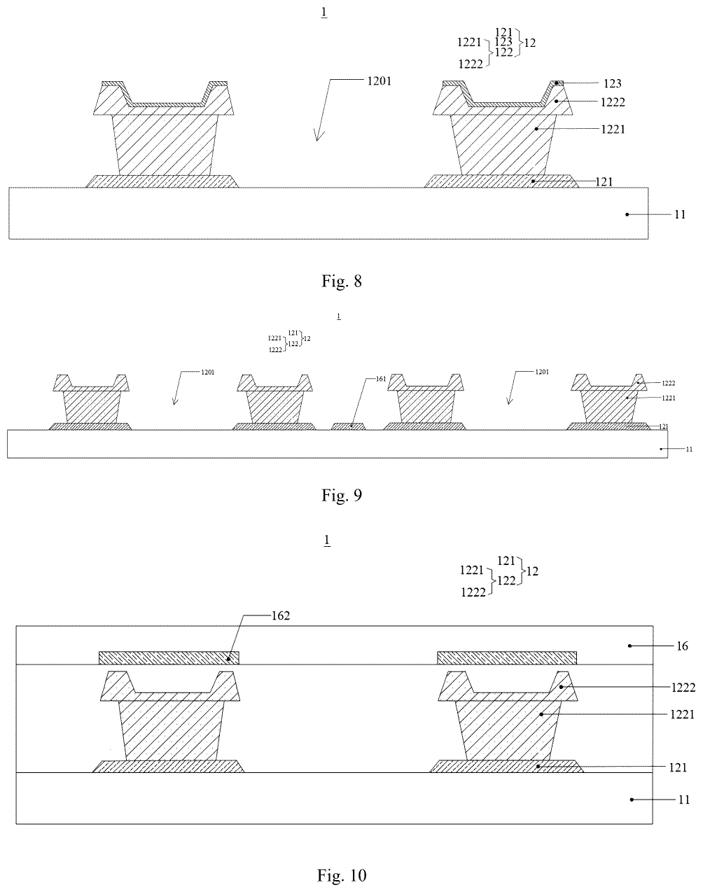

The inventors have found that when wet etching is used to pattern the organic material layer and/or the inorganic material layer to form the isolation portion 122, an etching solution easily corrodes the material layer, causing the morphology of the isolation portion 122 to fail to meet the requirements. To this end, in this embodiment, referring to FIG. 8, the isolation structure 12 further includes a blocking portion 123, which is located on a side of the isolation portion 122 away from the substrate 11. An orthographic projection of the blocking portion 123 on the substrate 11 coincides with the orthographic projection of the second isolation portion 1222 on the substrate 11. Illustratively, the blocking portion 123 may be located on a first surface of the second isolation portion 1222 away from the substrate 11, and the orthographic projection of the blocking portion 123 on the substrate 11 coincides with an orthographic projection of the first surface on the substrate 11. An orthographic projection, on the substrate 11, of the first surface of the second isolation portion 1222 away from the substrate 11 is located within an orthographic projection, on the substrate 11, of a second surface of the second isolation portion 1222 close to the substrate 11.

Optionally, the blocking portion 123 is made of a corrosion-resistant material. For example, a material of the blocking portion 123 includes titanium.

Further, a touch function can be integrated into the display panel 1. Specifically, it can be integrated into the display panel using an In-cell or on-cell method. For example, if the touch function is integrated into the encapsulation layer of the display panel using the In-cell method, referring to FIG. 9, the isolation structure 12 defining one isolation opening 1201, the adjacent isolation structures 12 are separately arranged, and a gap is provided between adjacent isolation structures 12. The display panel 1 includes a first touch trace 161 disposed in the same layer as the conductive portion 121, the first touch trace 161 is located in the gap between the adjacent isolation structures 12, and the first touch trace 161 is insulated from the conductive portion 121. If the touch function is integrated into the display panel 1 using the on-cell method, the isolation structure 12 is a mesh structure, and referring to FIG. 10, the isolation structure 12 encircling a plurality of isolation openings 1201, the display panel 1 further includes a touch functional layer 16 located on the side of the isolation structure 12 away from the substrate 11. The touch functional layer 16 includes a plurality of second touch traces 162. In order to reduce the obstruction of light generated from the light-emitting device by each of the second touch traces 162, an orthographic projection of the second touch trace 162 on the substrate 11 at least partially overlaps with an orthographic projection of the isolation structure 12 on the substrate 11.

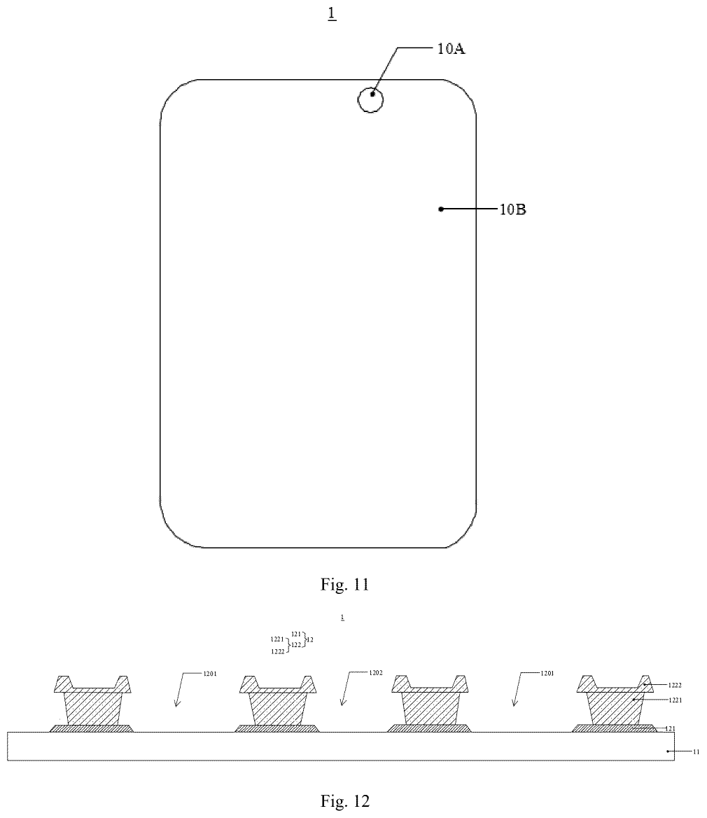

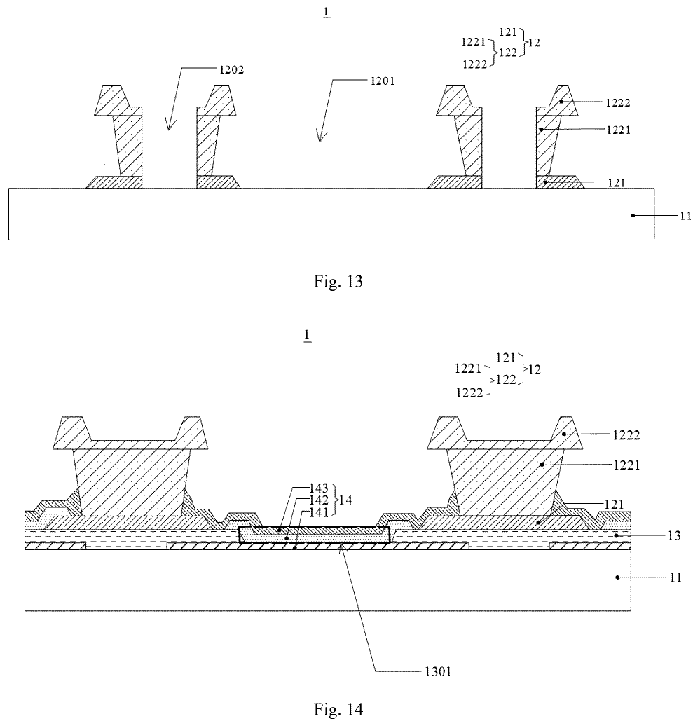

Further, in order to improve the sensitivity of an optical sensor (e.g., a camera) located below the display panel 1, in this embodiment, referring to FIGS. 11 and 12, the display panel 1 includes a first active area 10A and a second active area 10B at least partially surrounding the first active area 10A, where the optical sensor is disposed below the first active area 10A. Each of the isolation structures 12 located in the first active area 10A and the second active area 10B includes an isolation opening 1201, and the isolation structure 12 located in the first active area 10A further includes a light-transmitting opening 1202, that is, the isolation structure 12 is formed with the isolation opening 1201 and the light-transmitting opening 1202 in the first active area 10A, and the isolation structure 12 is formed with only the isolation opening 1201 in the second active area 10B. In the first active area 10A, the light-transmitting opening 1202 is located between adjacent isolation openings 1201, and an orthographic projection of the light-transmitting opening 1202 on the substrate 11 does not overlap with an orthographic projection of the isolation portion 122 on the substrate 11. Illustratively, referring to FIG. 13, the light-transmitting opening 1202 may also be disposed at the position of the groove 12221 of the second isolation portion 1222, in detail, it is possible to provide the light-transmitting opening 1202 at a position corresponding to the groove 12221 after the formation of the isolation structure 12, and the orthographic projection of the light-transmitting opening 1202 on the substrate 11 being located in an orthographic projection, on the substrate 11, of the groove 12221 on the side of the second isolation portion 1222 away from the substrate 11.

In order to ensure that the light-transmitting opening 1202 has good light transmittance, a light-shielding film layer is not prepared in the light-transmitting opening 1202, for example, the light-emitting material layer and an opaque conductive layer are not evaporated in the light-transmitting opening. In addition, a film layer structure at the position of the light-transmitting opening 1202 in the substrate 11 can be adjusted, for example, the opaque film layer is avoided at the position of the light-transmitting opening 1202. In this way, the light transmittance of an area at the position of the light-transmitting opening 1202 can be increased to ensure that the optical sensor can capture ambient light of a sufficient intensity.

Further, in this embodiment, referring to FIG. 14, the display panel 1 further includes a pixel defining layer 13, where the pixel defining layer 13 is located on one side of the substrate 11, and the isolation structure 12 is located on a side of the pixel defining layer 13 away from the substrate 11.

The pixel defining layer 13 defines a plurality of pixel openings 1301 on the substrate 11. An orthographic projection of each of the pixel openings 1301 on the substrate 11 is located within an orthographic projection of the isolation opening 1201 on the substrate 11, that is, an area of the orthographic projection of the pixel opening 1301 on the substrate 11 is smaller than an area of the orthographic projection of the isolation opening 1201 on the substrate 11. An orthographic projection of the second isolation portion 1222 on the substrate 11 is located within an orthographic projection of the pixel defining layer 13 on the substrate 11. On the same side facing the corresponding isolation opening the isolation opening 1201, the second isolation portion 1222 extends from the conductive portion 121 by a distance less than half a distance that the pixel defining layer extends from the second isolation portion 1222, and it is designed to ensure that the evaporation electrode can overlap with the conductive portion 121 without excessively obstructing the inorganic encapsulation layer, thereby facilitating uniform film formation of the inorganic encapsulation layer.

Referring again to FIG. 12, the display panel 1 further includes light-emitting devices 14, each of the light-emitting devices 14 is at least partially located in the pixel opening 1301. In the direction away from the substrate 11, the light-emitting device 14 includes a first electrode 141, a light-emitting material layer 142 and a second electrode 143 that are stacked, where the first electrode 141 is disposed on a side of the pixel defining layer 13 close to the substrate 11, at least part of the first electrode 141 is exposed from the pixel opening 1301, an orthographic projection of the first electrode 141 on the substrate 11 partially overlaps with the orthographic projection of the isolation structure 12 on the substrate 11, the second electrode 143 overlaps with the conductive portion 121, and the second electrode 143 may cover a side of the conductive portion 121 away from the substrate 11 and extends to an end of the first isolation portion 1221 close to the substrate 11, that is, the second electrode 143 may overlap with the first isolation portion 1221. For example, the first electrode 141 can be an anode of the light-emitting device 14, and the second electrode 143 can be a cathode of the light-emitting device 14.

In this embodiment, the isolation structure 12 may define a plurality of isolation openings 1201. The arrangement of the isolation structure 12 can form film layers of light-emitting devices of different colors in different isolation openings 1201 without a fine metal mask, thereby reducing the preparation cost of the display panel. The isolation structure 12 may isolate the light-emitting material layer 142 and the second electrode 143 in the light-emitting device, so that different light-emitting devices 14 are independent of each other, thereby improving crosstalk between adjacent light-emitting devices 14 and enhancing the display effect. Furthermore, adjacent light-emitting devices 14 are independent of each other and can be independently encapsulated to improve the encapsulation yield. Furthermore, due to the presence of the isolation structure 12, each of the light-emitting material layer 142 and the second electrode 143 in the light-emitting device 14 of each color in the display panel can be prepared over its entire surface first and then patterned, thereby eliminating the need for a fine metal mask and reducing the preparation cost of the display panel.

In this embodiment, the light-emitting device 14 can be a single-layer device or a stacked device. If the light-emitting device 14 is a single-layer device, the light-emitting material layer 142 includes only one emission layer. If the light-emitting device 14 is a stacked device, the light-emitting material layer 142 includes at least two emission layers that are stacked. In the following, the light-emitting device 14 is taken as a stacked device as an example. At least two emission layers 142 in the light-emitting material layer 142 have the same color. The light-emitting material layer 142 further includes a charge generation layer located between adjacent emission layers.

The following description takes the light-emitting device 14 as a double stacked device as an example. Referring to FIG. 13, in the direction away from the substrate 11, the light-emitting material layer 142 includes a hole injection layer (HIL), a first hole transport layer (HTL1), a first electron-blocking layer (EBL1), a first emission layer (EML1), a first hole block layer (HBL1), a first electron transport layer (ETL1), an N-type charge generation layer (N-CGL), a P-type charge generation layer (P-CGL), a second hole transport layer (HTL2), a second electron-blocking layer (EBL2), a second emission layer (EML2), a second hole block layer (HBL2), a second electron transport layer (ETL2) and an electron injection layer (EIL) that are stacked in sequence. In order to avoid a short circuit between the anode and the cathode of the light-emitting device and affecting the display effect, in this embodiment, orthographic projections of the hole injection layer, the first hole transport layer, the N-type charge generation layer and the second hole transport layer on the substrate 11 are located outside the orthographic projection of the conductive portion 121 on the substrate 11, so as to prevent the above-mentioned film layer from connecting to the second electrode 143 (cathode) through the conductive portion 121, which could result in a short circuit between the first electrode 141 and the second electrode 143.

Further, in this embodiment, referring to FIG. 14, the display panel 1 further includes a first encapsulation layer 151. The first encapsulation layer 151 includes a plurality of encapsulation units 1511 for encapsulating different light-emitting devices 14. Two adjacent encapsulation units 1511 for encapsulating light-emitting devices 14 of different colors are disconnected on the side of the isolation structure 12 away from the substrate 11, and a gap exists between the encapsulation unit 1511 and the isolation structure 12 on the side of the isolation structure 12 away from the substrate 11. Two adjacent encapsulation units 1511 for encapsulating light-emitting devices 14 of the same color are connected to each other on the side of the isolation structure 12 away from the substrate 11.

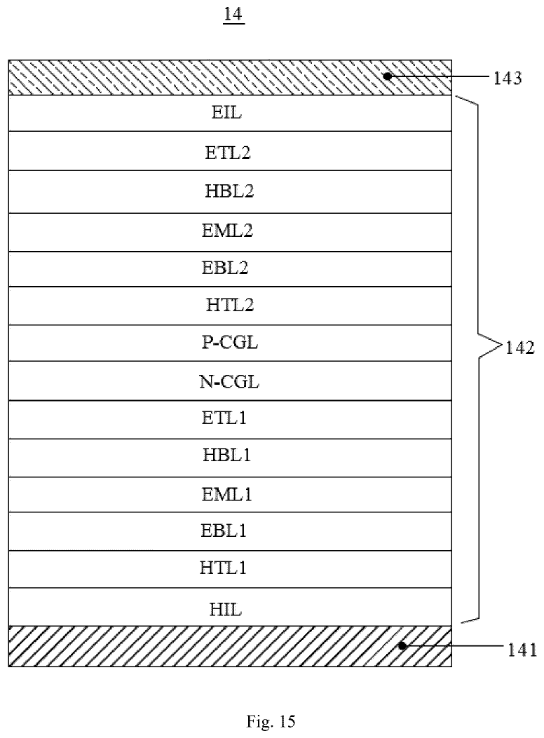

A film thickness of the encapsulation unit 1511 is uniform on a side wall of the isolation structure 12 formed with the isolation opening 1201, and in addition, a film thickness of the encapsulation unit 1511 within the isolation opening does not differ much than a film thickness of the encapsulation unit on the side wall of the isolation structure 12, which allows the encapsulation unit 1511 to have no weak spot where the film thickness is particularly small, so that the stress resistance of the encapsulation unit 1511 can be increased when the display panel is deformed. The thicker the film thickness of the encapsulation unit 1511, the smaller the corresponding stress and the stronger the stress resistance. As shown in FIG. 15, the maximum stress of the film layer rapidly decays with the increase of the film thickness. For example, when the film thickness changes from 0.15 microns to 0.45 microns, the maximum stress of the film layer drops from about 1000 MPa to about 180 MPa, and the stress of the film layer is reduced to about ⅙ of the original stress.

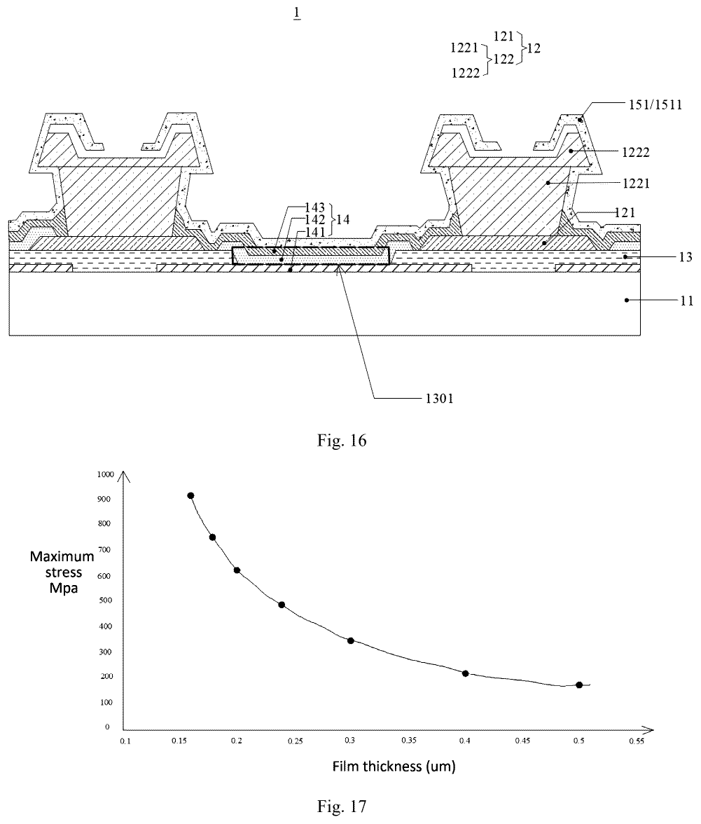

In a possible implementation, referring to FIG. 16, a material of the isolation structure 12 includes a light-absorbing material, and the display panel 1 further includes filter units 17 on a side of the encapsulation units 1511 away from the substrate 11, each of the filter units 17 being filled in the isolation opening 1201. Illustratively, an orthographic projection of the filter unit 17 on the substrate 11 partially overlaps with the orthographic projection of the second isolation portion 1222 on the substrate 11.

Illustratively, the second isolation portion 1222 may be disposed on a side of the filter unit 17 away from the substrate 11, where a light output color of the filter unit 17 is the same as a light-emitting color of the light-emitting device 14 within the isolation opening 12. Such a design can reduce color crosstalk between adjacent light-emitting devices 14 and improve the display effect of the display panel.

In a possible implementation, referring to FIG. 17, in this embodiment, the display panel 1 further includes a second encapsulation layer 152. The second encapsulation layer 152 is located on a side of the first encapsulation layer 151 away from the substrate 11. The second encapsulation layer 152 has a flat surface on the side away from the substrate 11.

Optionally, the second encapsulation layer 152 fills the gap between the encapsulation unit 1511 and the isolation structure 12.

Further, referring again to FIG. 17, the display panel 1 further includes a third encapsulation layer 153 located on a side of the second encapsulation layer 152 away from the substrate 11.

Optionally, the first encapsulation layer 151 and the third encapsulation layer 153 are inorganic encapsulation layers, and the second encapsulation layer 152 is an organic encapsulation layer. For example, the first encapsulation layer 151 and the third encapsulation layer 153 may be formed by means of chemical vapor deposition (CVD), and the second encapsulation layer 152 may be formed by means of ink-jet printing (IJP).

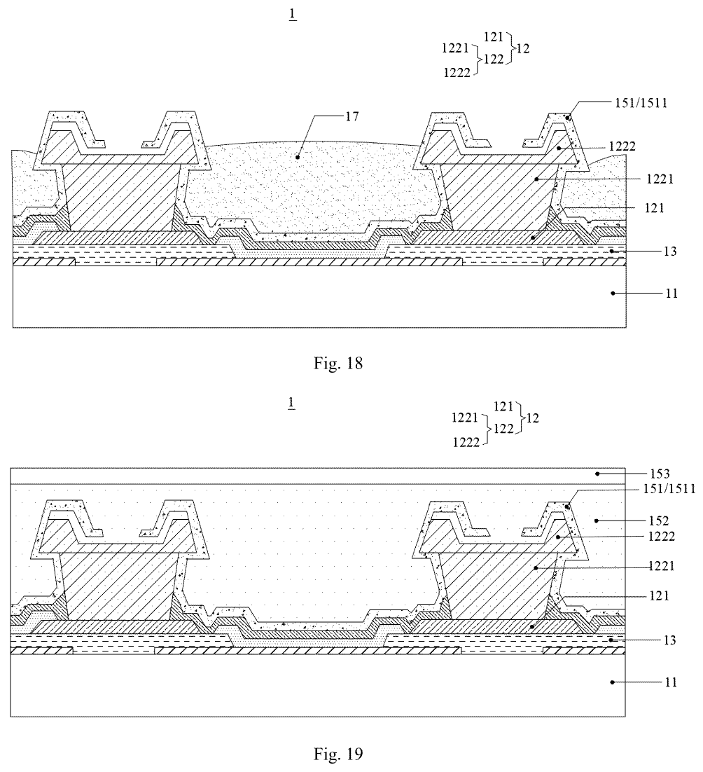

Based on the same inventive concept, referring to FIG. 18, this embodiment further provides a method for preparing a display panel, which will be described in detail below.

In step S11, a substrate is provided.

In this embodiment, the substrate is of a multi-layer structure, and the substrate includes at least a plurality of metal layers and an insulating layer located between adjacent metal layers. A pixel drive circuit for providing driving signals to light-emitting devices is formed in the substrate.

In step S12, isolation structures are prepared on the substrate, so that the isolation structures define isolation openings on the substrate.

In this embodiment, each of the isolation structures includes a conductive portion and an isolation portion, where the isolation portion includes a first isolation portion and a second isolation portion, the conductive portion, the first isolation portion and the second isolation portion being stacked in a direction away from the substrate, and the second isolation portion extending relative to the first isolation portion toward a corresponding one of the isolation openings. An orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate.

The isolation structure prepared above not only breaks an entire surface of an evaporated film layer at a position of an undercut structure formed by the first isolation portion and the second isolation portion, but also increases the flow smoothness of a film-forming material on a surface of the isolation structure when an inorganic encapsulation layer is prepared, so that the film-forming material continuously forms a film on the surface of the isolation structure, forming an inorganic encapsulation layer with a relatively uniform film thickness, thereby improving the stress resistance and encapsulation effect of the film layer of the inorganic encapsulation layer.

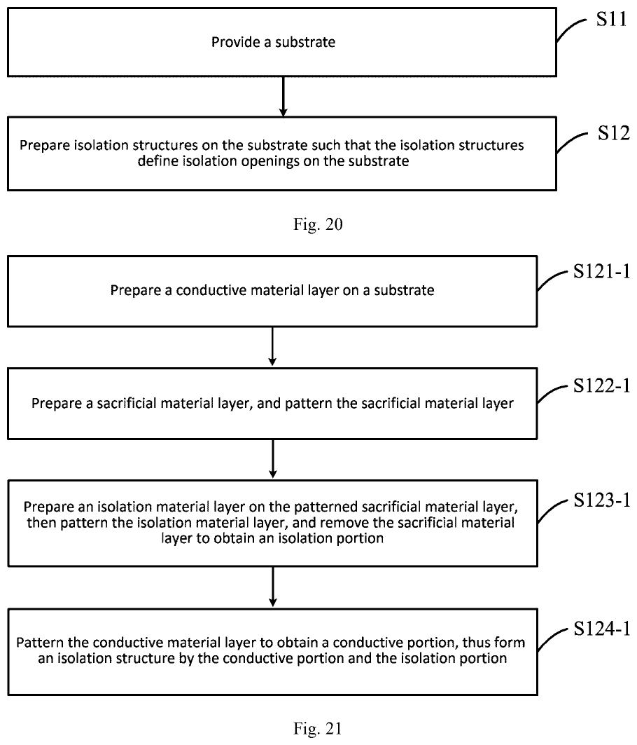

In a first implementation of this embodiment, referring to FIGS. 19 and 20, step S12 may also be implemented in the following manner.

In step S121-1, a conductive material layer 20 is prepared on a substrate 11.

In step S122-1, a sacrificial material layer 40 is prepared, and the sacrificial material layer 40 is patterned.

In the present step, the sacrificial material layer 40 may be prepared as follows:
forming the sacrificial material layer 40 by printing or spin-coating with an organic material; or
forming the sacrificial material layer 40 laterally by means of metal deposition; or
forming a first composite film layer including an organic material layer and a metal layer that are stacked, the first composite film layer serving as the sacrificial material layer 40.

In step S123-1, an isolation material layer 30 is prepared on the patterned sacrificial material layer 40, then the isolation material layer 30 is patterned, and the sacrificial material layer is removed to obtain an isolation portion 122.

In this embodiment, the isolation material layer 30 may be prepared as follows:
preparing the isolation material layer 30 on the patterned sacrificial material layer 40 by printing or spin-coating with an organic material; or
depositing an inorganic material layer on the patterned sacrificial material layer 40 by means of chemical vapor deposition, the inorganic material layer serving as the isolation material layer 30; or
forming a second composite film layer including an organic material layer and the inorganic material layer, the second composite film layer serving as the isolation material layer 30.

In step S124-1, the conductive material layer 20 is patterned to obtain a conductive portion 121, and the conductive portion 121 and the isolation portion 122 form an isolation structure 12.

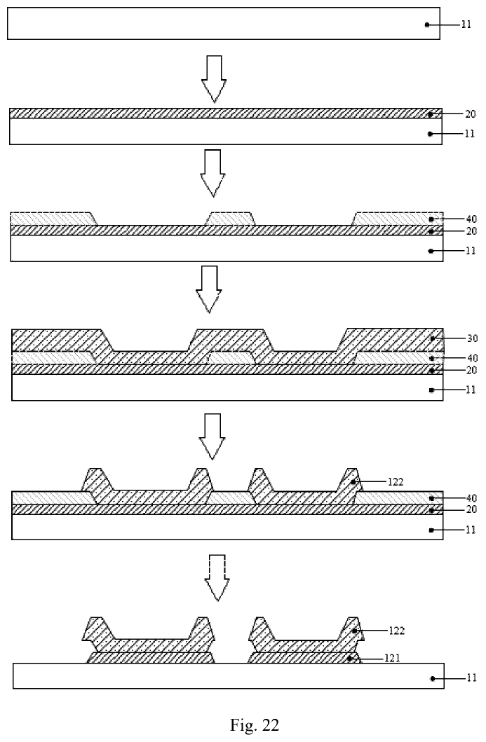

This embodiment further provides a second implementation similar to the first implementation, the main difference between the two lies in whether the conductive portion 121 is formed by a patterning process immediately after the conductive material layer 20 is prepared, or the conductive portion is formed by patterning the conductive material layer 20 after the isolation portion 122 is obtained. Referring to FIGS. 21 and 22, in the second implementation, step S12 may also be implemented in the following manner.

In step S121-2, the conductive material layer 20 is prepared on the substrate 11, and the conductive material layer 20 is patterned to obtain the conductive portion 121.

In step S122-2, a sacrificial material layer 40 is prepared, and the sacrificial material layer 40 is patterned.

In the present step, the sacrificial material layer 40 may be prepared as follows:
forming the sacrificial material layer 40 by printing or spin-coating with an organic material; or
forming the sacrificial material layer 40 laterally by means of metal deposition; or
forming a first composite film layer including an organic material layer and a metal layer that are stacked, the first composite film layer serving as the sacrificial material layer 40.

In step S123-2, an isolation material layer 30 is prepared on the patterned sacrificial material layer, then the isolation material layer 30 is patterned, and the sacrificial material layer is removed to obtain an isolation portion 122, thus the conductive portion 121 and the isolation portion 122 form an isolation structure.

In this embodiment, the isolation material layer 30 may be prepared as follows:
preparing the isolation material layer 30 on the patterned sacrificial material layer 40 by printing or spin-coating with an organic material; or
depositing an inorganic material layer on the patterned sacrificial material layer 40 by means of chemical vapor deposition, the inorganic material layer serving as the isolation material layer 30; or
forming a second composite film layer including an organic material layer and the inorganic material layer, the second composite film layer serving as the isolation material layer 30.

Compared with the method of forming an I-shaped or T-shaped isolation structure by dry etching and wet etching of the metal layer, the isolation structure prepared using the above-described method has a shape and a lateral recess depth that are easier to control, and can reduce the risk of foreign matter residues in the process.

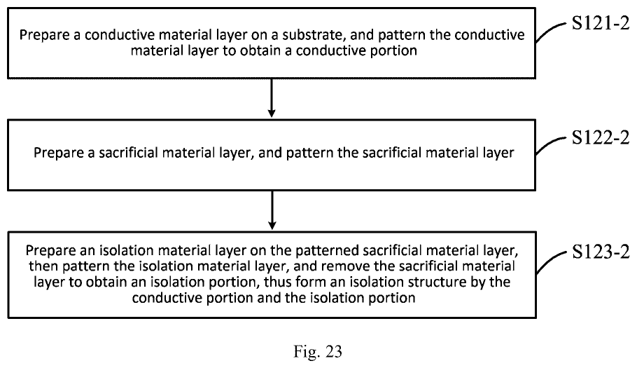

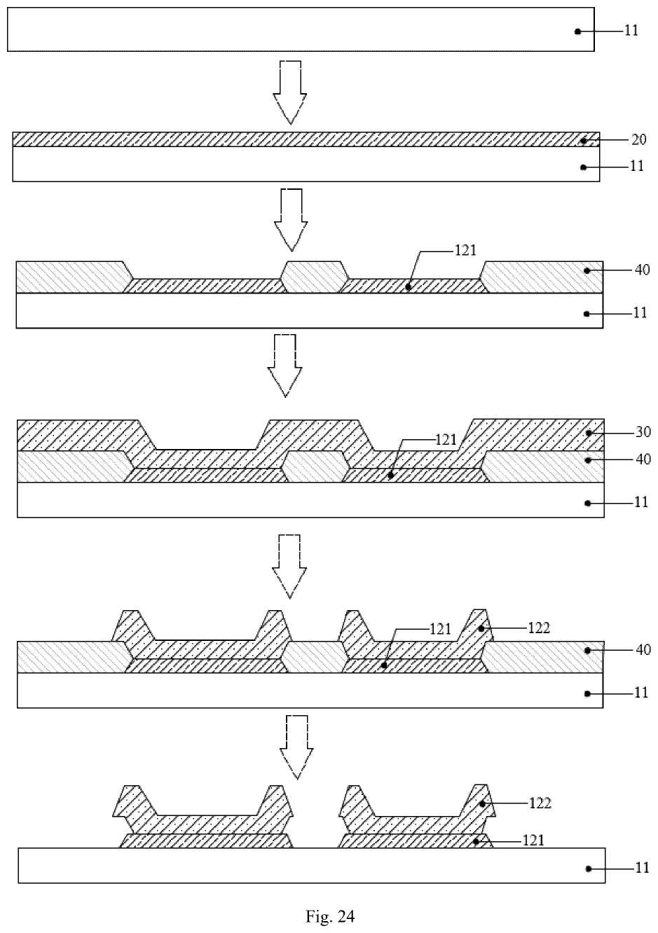

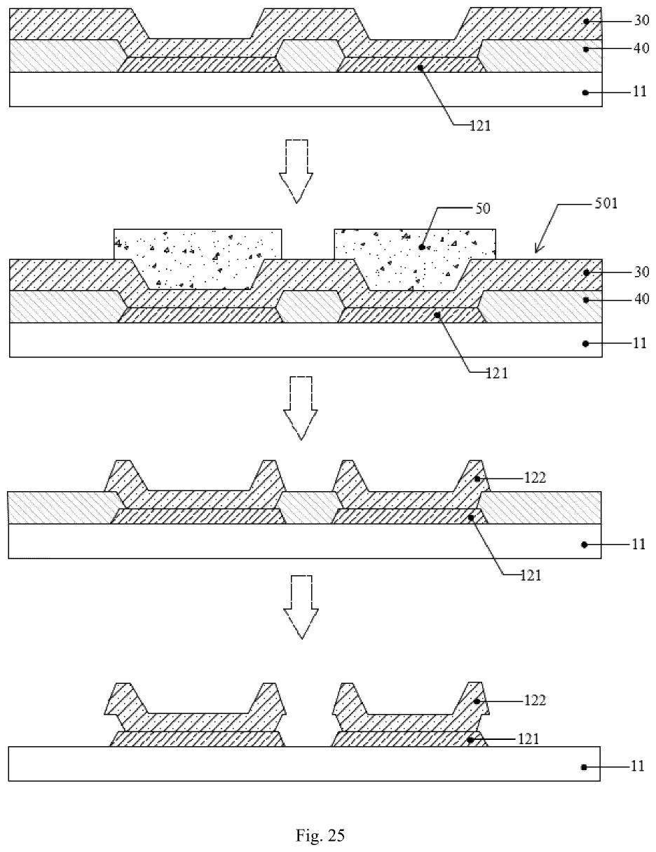

Further, referring to FIG. 23, in this embodiment, steps S123-1 and S123-2 can be implemented in the following manner.

First, the isolation material layer 30 is prepared on the patterned sacrificial material layer 40;
next, a photoresist layer 50 is prepared on a side of the isolation material layer 30 away from the substrate 11; and
the photoresist layer 50 is then patterned such that an adhesive layer opening 501 is formed in the photoresist layer 50, where an orthographic projection of the adhesive layer opening 501 on the substrate 11 is located outside an orthographic projection of an opening in the sacrificial material layer 40 on the substrate 11.

Finally, the isolation material layer 30 is etched through the adhesive layer opening 501, and the sacrificial material layer 40 is removed to obtain the isolation portion 122.

Based on the same inventive concept, an embodiment of the present application further provides an electronic device, which includes a display panel provided in the present application, or includes a display panel prepared according to a method for preparing a display panel provided in the present embodiment. The electronic device may include devices with a display function such as a mobile phone, a tablet computer, a smart wearable device, a television, a laptop computer, and a display.

Embodiments of the present application provide a display panel, a method for preparing a display panel, and an electronic device. In the display panel, a second isolation portion extends relative to a first isolation portion to form an undercut structure at which an entire surface of an evaporated film layer may be disconnected. In addition, an orthographic projection of a conductive portion on a substrate at least partially coincides with an orthographic projection of the second isolation portion on the substrate, and an orthographic projection of the first isolation portion on the substrate is located within the orthographic projection of the conductive portion on the substrate, which allows a surface on a side of an isolation structure facing an isolation opening to form a guide surface with good flow smoothness. In the process of preparing an inorganic encapsulation layer, a film-forming material may move smoothly along the surface, so that the film-forming material continuously forms a film on the surface, forming an inorganic encapsulation layer with a relatively uniform film thickness, thereby improving the stress resistance and encapsulation effect of the film layer of the inorganic encapsulation layer.

The foregoing descriptions are merely exemplary embodiments of the present application, but are not intended to limit the present application. For those skilled in the art, the present application may have various modifications and variations. Any modifications, equivalent substitutions, improvements, etc. made within the spirit and principle of the present application should fall within the scope of protection of the present application.

1. A display panel, characterized display-panel comprising:
a substrate; and
an isolation structure, located on one side of the substrate, and the isolation structure encircling at least one of isolation openings;
wherein the isolation structure comprises a conductive portion and an isolation portion;
the isolation portion comprises a first isolation portion and a second isolation portion, the conductive portion, the first isolation portion and the second isolation portion being stacked in a direction away from the substrate, and the second isolation portion extending relative to the first isolation portion toward a corresponding one of the isolation openings; and
an orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate.

2. The display panel according to claim 1, wherein a first included angle between a side of the second isolation portion facing the substrate and a side of the first isolation portion facing the corresponding isolation opening is an obtuse angle; and
a groove recessed toward the substrate is formed on a side of the second isolation portion away from the substrate.

3. The display panel according to claim 1, wherein a side of the second isolation portion comprises a flat surface on a side thereof away from the substrate; and
the first isolation portion and the second isolation portion are made of any one of the following materials;
an inorganic material, an organic material and a conductive metal material.

4. The display panel according to claim 1, wherein an orthographic projection on the substrate, of a bottom surface on a side of the first isolation portion facing the substrate is located within an orthographic projection, on the substrate, of a top surface on a side of the conductive portion away from the substrate; and
the orthographic projection of the conductive portion on the substrate is located within the orthographic projection of the second isolation portion on the substrate, the first isolation portion has a first end which is a side of the first isolation portion in contact with the conductive portion and is close to the corresponding isolation opening, the second isolation portion has a second end on a side of the second isolation portion close to the isolation opening, and a connecting surface of the first end and the second end forms a preset included angle with a plane where the substrate is located, the preset included angle being greater than 20°.

5. The display panel according to claim 2, wherein a second included angle between a side wall of the first isolation portion facing the isolation opening and a side wall of the conductive portion facing the isolation opening is an obtuse angle; and
the second included angle is larger than the first included angle.

6. The display panel according to claim 1, wherein a thickness of the isolation portion is 1 to 10 times a thickness of the conductive portion.

7. The display panel according to claim 1, wherein the isolation structure further comprises a blocking portion located on a side of the isolation portion away from the substrate;
an orthographic projection of the blocking portion on the substrate coincides with the orthographic projection of the second isolation portion on the substrate; and
the blocking portion is located on a first surface of the second isolation portion away from the substrate.

8. The display panel according to claim 1, wherein the isolation structure defining one isolation opening a gap is provided between adjacent isolation structures, and the display panel further comprises a first touch trace disposed in the same layer as the conductive portion, the first touch trace being located in the gap between the adjacent isolation structures.

9. The display panel according to claim 1, wherein the display panel comprises a first active area and a second active area at least partially surrounding the first active area;
the isolation structures located in first active area and the second active area, and the isolation structure encircling at least one of isolation openings; and
the isolation structure located in the first active area further encircling a light-transmitting opening;
wherein the light-transmitting opening is located between adjacent isolation openings, and an orthographic projection of the light-transmitting opening on the substrate does not overlap with the orthographic projection of the isolation portion on the substrate; and
the orthographic projection of the light-transmitting opening on the substrate is located within an orthographic projection, on the substrate, of a groove on a side of the second isolation portion away from the substrate.

10. The display panel according to claim 1, wherein the display panel further comprises a pixel defining layer located on one side of the substrate, the isolation structure being located on a side of the pixel defining layer away from the substrate;
the pixel defining layer defines a plurality of pixel openings on the substrate, the pixel openings being in one-to-one correspondence with the isolation openings, and an orthographic projection of one of the pixel openings on the substrate is located within an orthographic projection of a corresponding one of the isolation openings on the substrate; and
the orthographic projection of the second isolation portion on the substrate is located within an orthographic projection of the pixel defining layer on the substrate.

11. The display panel according to claim 26, wherein the light-emitting material layer comprises at least two emission layers, that are stacked:
the at least two emission layers have the same color, and the light-emitting material layer further comprises a charge generation layer located between adjacent emission layers;
the light-emitting material layer comprises a hole injection layer, a first hole transport layer, a first electron-blocking layer, a first emission layer, a first hole block layer, a first electron transport layer, an N-type charge generation layer, a P-type charge generation layer, a second hole transport layer, a second electron-blocking layer, a second emission layer, a second hole block layer, a second electron transport layer, and an electron injection layer that are sequentially stacked in the direction away from the substrate; and
orthographic projections of the hole injection layer, the first hole transport layer, the N-type charge generation layer, and the second hole transport layer on the substrate are located outside the orthographic projection of the conductive portion on the substrate.

12. The display panel according to claim 26, wherein the display panel further comprises a first encapsulation layer;
the first encapsulation layer comprises a plurality of encapsulation units, each of the encapsulation unit is for encapsulating each of the light-emitting devices;
two adjacent encapsulation units for encapsulating the light-emitting devices of different colors are disconnected on a side of the isolation structure away from the substrate, and a gap is provided between the isolation structure and the encapsulation unit on the side of the isolation structure away from the substrate; and
two adjacent encapsulation units for encapsulating the light-emitting devices of the same color are connected to each other on the side of the isolation structure away from the substrate.

13. (canceled)

14. The display panel according to claim 12, wherein the display panel further comprises a second encapsulation layer;
the second encapsulation layer is located on a side of the first encapsulation layer away from the substrate, and the second encapsulation layer has a flat surface on a side thereof away from the substrate;
the display panel further comprises a third encapsulation layer arranged on the side of the second encapsulation layer away from the substrate; and
the first encapsulation layer and the third encapsulation layer are inorganic encapsulation layers, and the second encapsulation layer is an organic encapsulation layer.

15. An electronic device comprising:
a substrate; and
an isolation structure, located on one side of the substrate, and the isolation structure encircling at least one of isolation openings on the substrate;
wherein the isolation structure comprising a conductive portion and an isolation portion;
the isolation portion comprising a first isolation portion and a second isolation portion, the conductive portion, the first isolation portion and the second isolation portion being stacked in a direction away from the substrate, and the second isolation portion extending relative to the first isolation portion toward a corresponding one of the isolation openings; and
an orthographic projection of the conductive portion on the substrate at least partially coincides with an orthographic projection of the second isolation portion on the substrate, and an orthographic projection of the first isolation portion on the substrate is located within the orthographic projection of the conductive portion on the substrate.

16-20. (canceled)

21. The display panel according to claim 1, wherein
the second isolation portion surrounding the periphery of each isolation opening comprises a first isolation sub-portion and a second isolation sub-portion separated from each other, and orthographic projections of the first isolation sub-portion and the second isolation sub-portion on the substrate extend relative to opposite sides of the orthographic projection of the first isolation portion on the substrate, respectively.

22. The display panel according to claim 1, wherein on a first cross-section perpendicular to a plane where the substrate is located and in a direction of a line connecting centers of two adjacent isolation openings, a shape of the first isolation portion is an inverted trapezoid.

23. The display panel according to claim 1, wherein the orthographic projection of the second isolation portion on the substrate is located within the orthographic projection of the conductive portion on the substrate.

24. The display panel according to claim 1, wherein the isolation structure formed a mesh structure, the isolation structure encircling a plurality of isolation openings, and the display panel further comprises a touch functional layer located on a side of the isolation structure away from the substrate, the touch functional layer comprising a plurality of second touch traces, and an orthographic projection of each of the second touch traces on the substrate at least partially overlapping with an orthographic projection of the isolation structure on the substrate.

25. The display panel according to claim 10, wherein
on the same side facing the corresponding isolation opening, the second isolation portion extends from the conductive portion by a distance less than half a distance that the pixel defining layer extends from the second isolation portion.

26. The display panel according to claim 10, wherein the display panel further comprises a plurality of light-emitting devices, each of the light-emitting devices being at least partially located in the pixel opening, and in the direction away from the substrate, the light-emitting device comprises a first electrode, a light-emitting material layer and a second electrode that are stacked, the second electrode overlapping with the conductive portion;
the second electrode covers a side of the conductive portion away from the substrate and extends to an end of the first isolation portion close to the substrate; and
the first electrode is disposed on a side of the pixel defining layer close to the substrate, at least part of the first electrode is exposed from the pixel opening, and an orthographic projection of the first electrode on the substrate partially overlaps with an orthographic projection of the isolation structure on the substrate.
